(19) United States
(12) Patent Application Publication
(10) Pub. No.: US 2014/0332834 A1
(43) Pub. Date: Nov. 13, 2014

(54) SUBSTRATE FOR AN OPTO-ELECTRIC DEVICE

(71) Applicant: ALCOA INC., Pittsburgh, PA (US)

(72) Inventors: Thomas L. Levendusky, Greensburg, PA (US); Kirit Shah, Monroeville, PA (US)

(21) Appl. No.: 14/192,167

(22) Filed: Feb. 27, 2014

Related U.S. Application Data
(60) Provisional application No. 61/785,206, filed on Mar. 14, 2013.

(51) Int. Cl. H01L 31/0236; H01L 33/44; H01L 31/18; H01L 33/48

(52) U.S. Cl. CPC H01L 31/02366; H01L 33/48; H01L 33/44; H01L 31/18
USPC 257/98; 257/432; 438/27; 438/65

(57) ABSTRACT

An opto-electric device has a substrate comprised of metal or plastic. The substrate in an uncoated condition has an average surface roughness Rz of 150 nm to 1500 nm. A dielectric coating coats the substrate and a non-thermally curable coating is directly on the dielectric coating. An electrode is on the non-thermally curable coating. The dielectric coating and the non-thermally curable coating are between the electrode and the substrate. A method of making an opto-electric device comprises: applying a dielectric coating to a substrate comprised of metal or plastic; applying a non-thermally curable coating directly on the dielectric coating; wherein applying a non-thermally curable coating comprises one of: roll coating, reverse roll coating, slot die coating, curtain coating and spray coating; curing the non-thermally curable coating; and placing an electrode on the non-thermally curable coating such that the dielectric coating and the non-thermally curable coating are between the electrode and the substrate.

### BACKGROUND

An opto-electric device is a device that provides for an optical effect in response to an electrical signal, or that generates an electrical signal in response to an optical stimulus. Examples of the first are light emitting diodes, such as organic light emitting diodes (OLED's) and electro chromic devices. Examples of the second are photovoltaic cells and optical sensors. An OLED is a light-emitting diode (LED) in which the emissive electroluminescent layer is a film of organic compound which emits light in response to an electric current. This layer of organic semiconductor is situated between two electrodes. Generally, at least one of these electrodes is transparent.

Generally, opto-electric devices are built upon glass substrates. There are many advantages to opto-electric devices having metal substrates, including increased durability, flexibility and heat dissipation properties relative to glass substrates. However, there have been barriers to opto-electric devices built upon metal substrates operating as efficiently as opto-electric devices built upon glass substrates.

### SUMMARY

In some embodiments, an opto-electric device comprises: a substrate, wherein the substrate is one of: metal or plastic and wherein the substrate in an uncoated condition has an average surface roughness Rz of 150 nm to 1500 nm; a dielectric coating on the substrate; a non-thermally curable coating directly on the dielectric coating; and an electrode on the non-thermally curable coating. The dielectric coating and the non-thermally curable coating are between the electrode and the substrate.

An opto-electric device is a device that provides for an optical effect in response to an electrical signal, or that generates an electrical signal in response to an optical stimulus. Examples of the first are light emitting diodes, such as organic light emitting diodes (OLED's) and electro chromic devices. Examples of the second are photovoltaic cells and optical sensors.

An uncoated condition means no insulating or planarizing layers are on the bare substrate.

Rz is the ten-point mean roughness as defined by Japanese Industrial Standards (1994). A section of standard length is sampled from the mean line on the roughness chart. The distance between the peaks and valleys of the sampled line is measured in the Y direction. Then the average peak is obtained among the five tallest peaks (Yp) and the average valley is obtained between the five lowest valleys (Yv). Rz is the sum of the average peak and the average valley. See FIG. 10.

In some embodiments, the substrate in an uncoated condition has an average surface roughness Rz of 150 nm to 300 nm. In other embodiments, the substrate in an uncoated condition has an average surface roughness Rz of 175 nm to 350 nm. In further embodiments, the substrate in an uncoated condition has an average surface roughness Rz of 200 nm to 350 nm. In some embodiments, the substrate in an uncoated condition has an average surface roughness Rz of 200 nm to 300 nm. In yet other embodiments, the substrate in an uncoated condition has an average surface roughness Rz of 150-1000 nm, 200-1000 nm, 300-1500 nm, 300-1000 nm, 400-1500 nm, 400-1000 nm, 500-1500 nm, 500-1000 nm, or 150-350 nm. In some embodiments, the substrate in an uncoated condition has an average surface roughness Rz as high as 1500 nm, 1250 nm, 1000 nm, 900 nm, 800 nm, 700 nm, 600 nm, 500 nm, 400 nm, or 300 nm. In some embodiments, the substrate in an uncoated condition has an average surface roughness Rz as low as 150 nm, 200 nm, 250 nm, 300 nm, 350 nm, 400 nm, 450 nm, 500 nm, 550 nm, or 600 nm.

In some embodiments, the substrate with the dielectric coating has an average surface roughness Rz of 35-250 nm. In other embodiments, the substrate with the dielectric coating has an average surface roughness Rz of 75 nm to 150 nm. In yet other embodiments, the substrate with the dielectric coating has an average surface roughness Rz of 90 nm to 110 nm. In further embodiments the substrate with the dielectric coating as an average surface roughness Rz of 100-200 nm, 35-200 nm, 50-250 nm, 50-200 nm, 50-150 nm, 35-150 nm, 35-100 nm, or 50-100 nm.

A dielectric coating is a coating that conducts a negligible amount of electricity. In some embodiments the dielectric coating has an electrical conductivity of less than a millionth (10−6) of a Siemens. In some embodiments, the dielectric coating comprises on of: an organic polymer and an inorganic polymer. Examples of organic polymers that may form the dielectric coating include acrylics, epoxies, polyesters and vinyls. Examples of inorganic polymers that may form the dielectric coating include SiO2 and SiN, and Al2O3. Any suitable organic or inorganic polymer may be used as the dielectric coating. In some embodiments, the thickness of the dielectric coating is in the range of 3 microns-30 microns. In some embodiments, the thickness of the dielectric coating is in the range of 6 microns-20 microns. In some embodiments, the thickness of the dielectric coating is in the range of 8-15 microns.

In some embodiments, the dielectric coating is a thermally curable coating. A thermally curable coating is a coating that cures at a temperature greater than 200° F. (95° C.). In some embodiments, the dielectric coating is a non-thermally curable coating.

A non-thermally curable coating is a coating that can be cured via a non-thermal method, i.e. a method that does not require the addition of heat, such as physical vapor deposition, chemical vapor deposition and non-thermal radiation. Examples of radiation that may be used to cure the non-thermally curable coating are ultra-violet light and electron beam radiation. Examples of non-thermally curable coatings include epoxy acrylates, acrylic acrylates and other radiation curable coatings. In some embodiments, the thickness of the non-thermally curable coating is in the range of 1-30 microns. In some embodiments, the thickness of the non-thermally curable coating is in the range of 3-18 microns. In some embodiments, the thickness of the non-thermally curable coating is in the range of 8-12 microns.

“Directly on the dielectric coating” means that there is no intermediate coating or layer between the dielectric coating and the non-thermally curable coating.

In some embodiments, the substrate comprises one of: an aluminum alloy, plastic, and steel. Examples of aluminum alloys that may form the substrate include 1xxx, 3xxx, 5xxx, 6xxx and 8xxx. In some embodiments, the thickness of the substrate is in the range of 0.15 mm-0.6 mm (0.006-0.024 inch). In some embodiments, the thickness of the substrate is in the range of 0.2 mm-0.45 mm (0.008-0.018 inch). In some embodiments, the thickness of the substrate is in the range of 0.25 mm-0.35 mm (0.010-0.014 inch).

In some embodiments, the opto-electric device further comprises a pretreatment coating between the substrate and the dielectric coating. Examples of pretreatment coatings that can be used on the substrate include phosphates, silanes, titanates and zirconates.

A method of making an opto-electric device comprises: applying a dielectric coating to a substrate, wherein the substrate is one of: metal or plastic; applying non-thermally curable coating directly on the dielectric coating, wherein applying a non-thermally curable coating comprises one of: roll coating, reverse roll coating, slot die coating, curtain coating and spray coating; curing the non-thermally curable coating; and placing an electrode on the non-thermally curable coating such that the dielectric coating and the non-thermally curable coating are between the electrode and the substrate.

In some embodiments, applying a dielectric coating comprises one of: roll coating, reverse roll coating, slot die coating, curtain coating, spray coating, physical vapor deposition and chemical vapor deposition or any suitable method of applying a coating. In some embodiments, applying a dielectric coating comprises reverse roll coating. In some embodiments, applying a dielectric coating comprises applying the dielectric coating in a continuous process, as opposed to a batch process.

Roll coating is the process of applying a coating to a flat substrate by passing it between rollers. Coating is applied by one auxiliary roller onto an application roll, which rolls across the conveyed flat substrate.

There are two types of roll coating: direct and reverse roll coating. In direct roll coating, the applicator roll rotates in the same direction as the substrate moves. In reverse roll coating, the applicator roll rotates in the opposite direction of the substrate. Slot die coating comprises forcing a coating liquid: out from a reservoir, through a slot by pressure and onto a substrate moving relative to the slot. Curtain coating comprises passing a horizontally flat substrate on a conveyor underneath a steady stream of coating material falling onto the substrate. Spray coating comprises coating a substrate with a liquid spray. More information regarding these coating techniques can be found in Modern Coating and Drying Technology, editors Edward Cohen & Edgar Gutoff, Wiley-VCH, Inc., isbn 1-56081-097-1, 1992, which is incorporated herein by reference.

In some embodiments, applying a non-thermally curable coating comprises one of: spray coating, roll coating and reverse roll coating. In some embodiments, applying a non-thermally curable coating comprises reverse roll coating. In some embodiments, applying a non-thermally curable coating comprises applying the non-thermally curable coating in a continuous process.

The coatings can be applied in batch or in continuous mode.

In some embodiments of the method of making an opto-electric device, the substrate comprises one of: an aluminum alloy, plastic, and steel.

In some embodiments of the method of making an opto-electric device, the dielectric coating comprises one of: an organic polymer and an inorganic polymer.

In some embodiments of the method of making an opto-electric device, the non-thermally curable coating is cured by one of: ultra-violet light and electron beam radiation.

In some embodiments of the method of making an opto-electric device, the method further comprises pretreating the substrate before applying the dielectric coating. Pretreating means cleaning, and if necessary, applying phosphate, silane, titanate and zirconate functionality to the aluminum surface to enhance adhesion of subsequent layers.

In some embodiments of the method of making an opto-electric device, the method further includes thermally curing the dielectric coating. In some embodiments of the method of making an opto-electric device, the method further include non-thermally curing the dielectric coating.

Thermally curing the dielectric coating means heating the dielectric coating at least until it reaches the temperature at which the coating cures. Non-thermally curing means curing via a curing method that does not require the addition of heat. Non-thermal methods include, but are not limited to, ultra-violet light and electron beam radiation.

Some embodiments of the method further comprise, finishing a surface of the substrate so that the surface of the substrate has an average surface roughness Rz of 150 nm to 350 nm. In some embodiments, the surface of the substrate is finished so that the surface of the substrate has an average surface roughness Rz of 175 nm to 350 nm. In other embodiments, the surface of the substrate is finished so that the surface of the substrate has an average surface roughness Rz of 200 nm to 350 nm. In another embodiment, the surface of the substrate is finished so that the surface of the substrate has an average surface roughness Rz of 200 nm to 300 nm. In yet other embodiments, the surface of the substrate is finished so that the surface of the substrate has an average surface roughness Rz of 150-1000 nm, 200-1000 nm, 300-1500 nm, 300-1000 nm, 400-1500 nm, 400-1000 nm, 500-1500 nm, 500-1000 nm, or 150-350 nm. In some embodiments, the surface of the substrate is finished so that the surface of the substrate has an average surface roughness Rz as high as 1500 nm, 1250 nm, 1000 nm, 900 nm, 800 nm, 700 nm, 600 nm, 500 nm, 400 nm, or 300 nm. In some embodiments, the surface of the substrate is finished so that the surface of the substrate has an average surface roughness Rz as low as 150 nm, 200 nm, 250 nm, 300 nm, 350 nm, 400 nm, 450 nm, 500 nm, 550 nm, or 600 nm.

In some embodiments wherein the substrate is a metal substrate, finishing comprises rolling. In other embodiments finishing comprises chemical brightening.

Rolling means use of machined rolls, oppositely opposed, wherein the metal substrate passes between the nip of the rolls. This reduces the thickness of the metal substrate, and under conditions where the rolls are polished, the metal substrate will have a bright surface.

Chemical brightening means use of acids at elevated temperatures, which selectively etch the metal surface. This etching removes the peaks on the metal surface, in turn yielding a surface with increased specularity.

### DESCRIPTION OF THE FIGURES

Reference is made to the following detailed description of exemplary embodiments considered in conjunction with the accompanying drawings, wherein

FIG. 1 is a side cross-section view of an OLED stack;

FIG. 2 is a side cross-section view of a second OLED stack;

FIG. 3 illustrates one method of making an opto-electric device;

FIG. 4 illustrates another embodiment of a method of making an opto-electric device;

FIG. 5 illustrates yet another embodiment of a method of making an opto-electric device;

FIG. 6 illustrates a further embodiment of a method of making an opto-electric device;

FIG. 7 illustrates another embodiment of a method of making an opto-electric device further;

FIG. 8 illustrates yet another embodiment of a method of making an opto-electric device; and

FIG. 9 illustrates a further embodiment of a method of making an opto-electric device.

FIG. 10 illustrates how to calculate Rz.

### DESCRIPTION

The present invention will be further explained with reference to the attached drawings, wherein like structures are referred to by like numerals throughout the several views. The drawings shown are not necessarily to scale, with emphasis instead generally being placed upon illustrating the principles of the present invention. Further, some features may be exaggerated to show details of particular components.

The figures constitute a part of this specification and include illustrative embodiments of the present invention and illustrate various objects and features thereof. Further, the figures are not necessarily to scale, some features may be exaggerated to show details of particular components. In addition, any measurements, specifications and the like shown in the figures are intended to be illustrative, and not restrictive. Therefore, specific structural and functional details disclosed herein are not to be interpreted as limiting, but merely as a representative basis for teaching one skilled in the art to variously employ the present invention.

Among those benefits and improvements that have been disclosed, other objects and advantages of this invention will become apparent from the following description taken in conjunction with the accompanying figures. Detailed embodiments of the present invention are disclosed herein; however, it is to be understood that the disclosed embodiments are merely illustrative of the invention that may be embodied in various forms. In addition, each of the examples given in connection with the various embodiments of the invention which is intended to be illustrative, and not restrictive.

Throughout the specification and claims, the following terms take the meanings explicitly associated herein, unless the context clearly dictates otherwise. The phrases “in one embodiment” and “in some embodiments” as used herein do not necessarily refer to the same embodiment(s), though it may. Furthermore, the phrases “in another embodiment” and “in some other embodiments” as used herein do not necessarily refer to a different embodiment, although it may. Thus, as described below, various embodiments of the invention may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

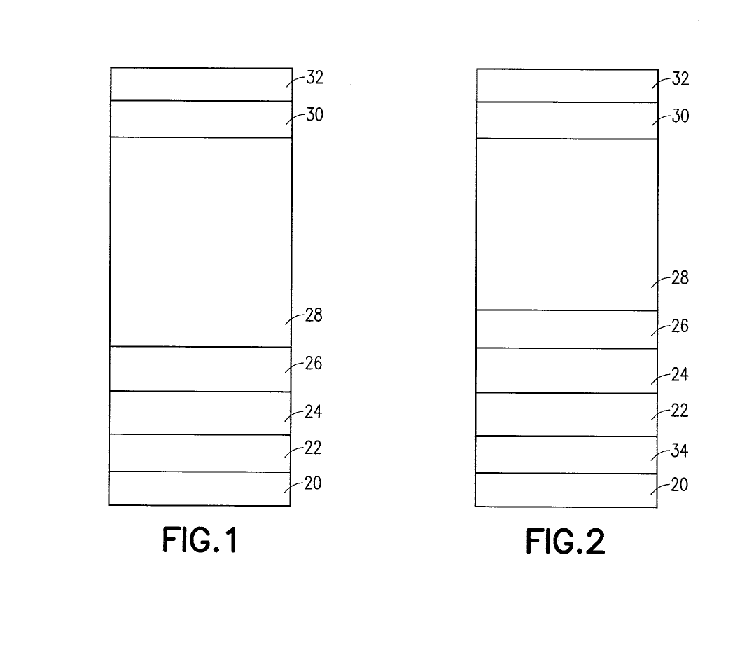

FIG. 1 shows an example of an OLED stack. A substrate 20 forms the base of the stack. A dielectric coating 22 is on top of the substrate. A non-thermally curable coating 24 is directly on top of the dielectric coating 22. A bottom electrode 26 is on top of the non-thermally curable coating. OLED stack layers 28 can be one or more OLED stack layers, such as an electron transport emission layer and a hole transport layer. A top electrode 30 is on top of the OLED stack layers 28. A glass or thin film encapsulation layer 32 encapsulates the entire device.

In some embodiments, of the above example, the substrate in an uncoated condition has an average surface roughness Rz of 150 nm to 350 nm. In some embodiments, the substrate in an uncoated condition has an average surface roughness Rz of 150 nm to 300 nm. In other embodiments, the substrate in an uncoated condition has an average surface roughness Rz of 175 nm to 350 nm. In further embodiments, the substrate in an uncoated condition has an average surface roughness Rz of 200 nm to 350 nm. In some embodiments, the substrate in an uncoated condition has an average surface roughness Rz of 200 nm to 300 nm. In yet other embodiments, the substrate in an uncoated condition has an average surface roughness Rz of of 150 nm to 1500 nm, 150-1000 nm, 200-1000 nm, 300-1500 nm, 300-1000 nm, 400-1500 nm, 400-1000 nm, 500-1500 nm, 500-1000 nm, or 150-350 nm.

In some embodiments of the above example, the substrate with the dielectric coating has an average surface roughness Rz of 100 nm to 200 nm. In other embodiments, the substrate with the dielectric coating has an average surface roughness Rz of 75 nm to 150 nm. In yet other embodiments, the substrate with the dielectric coating has an average surface roughness Rz of 90 nm to 110 nm. In further embodiments, the substrate with the dielectric coating has an average surface roughness Rz of 35-250 nm. In yet further embodiments the substrate with the dielectric coating as an average surface roughness 35-200 nm, 50-250 nm, 50-200 nm, 50-150 nm, 35-150 nm, 35-100 nm, or 50-100 nm.

In this example, the dielectric coating may be an organic polymer or inorganic polymer. Examples of organic polymers that may form the dielectric coating include acrylics, epoxies, polyesters and vinyls. Examples of inorganic polymers that may form the dielectric coating include SiO2, SiN & Al2O3. Any suitable organic or inorganic polymer may be used as the dielectric coating. In some embodiments, the dielectric constant of the dielectric coating is less than 5. In some embodiments, the dielectric constant of the dielectric coating is less than 3.

In some embodiments of the above example, the thickness of the dielectric coating is in the range of 3 microns-30 microns. In some embodiments, the thickness of the dielectric coating is in the range of 6 microns-20 microns. In some embodiments, the thickness of the dielectric coating is in the range of 8-15 microns.

In some embodiments of the above example, the dielectric coating is a thermally curable coating. In some embodiments, the dielectric coating is a non-thermally curable coating.

In some embodiments of the above example, the thickness of the non-thermally curable coating is in the range of 1-30 microns. In some embodiments, the thickness of the non-thermally curable coating is in the range of 3-18 microns. In some embodiments, the thickness of the non-thermally curable coating is in the range of 8-12 microns.

In some embodiments of the above example, the substrate comprises one of: an aluminum alloy and steel. Examples of aluminum alloys that may form the substrate include 1xxx, 3xxx, 5xxx and 6xxx. In some embodiments of the above example, the thickness of the substrate is in the range of 0.15 mm-0.6 mm (0.006-0.024 inch). In some embodiments, the thickness of the substrate is in the range of 0.2 mm-0.45 mm (0.008-0.018 inch). In some embodiments, the thickness of the substrate is in the range of 0.25 mm-0.35 mm (0.010-0.014 inch).

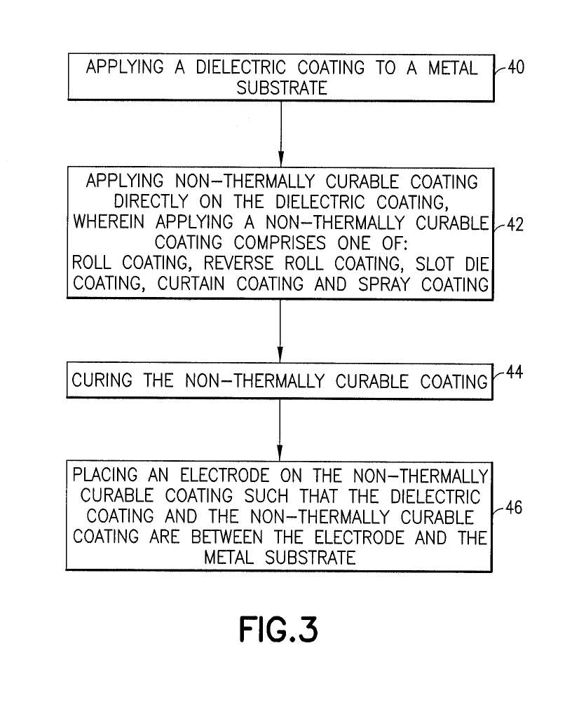

A second example of an OLED is shown in FIG. 2. The example shown in FIG. 2 is the same as the OLED stack in FIG. 1, except, the opto-electric device further comprises a pretreatment coating 34 between the substrate 20 and the dielectric coating 22. Examples of pretreatment coatings that can be used on the substrate include phosphates, silanes, titanates, zirconates, chrome phosphate, and those described in U.S. Pat. Nos. 5,059,258, 5,132,181 and 6,020,030.

FIG. 3 illustrates one method of making an opto-electric device comprising applying a dielectric coating to a substrate 40; applying non-thermally curable coating directly on the dielectric coating, wherein applying a non-thermally curable coating comprises one of: roll coating, reverse roll coating, slot die coating, curtain coating and spray coating 42; curing the non-thermally curable coating 44; and placing an electrode on the non-thermally curable coating such that the dielectric coating and the non-thermally curable coating are between the electrode and the substrate 46.

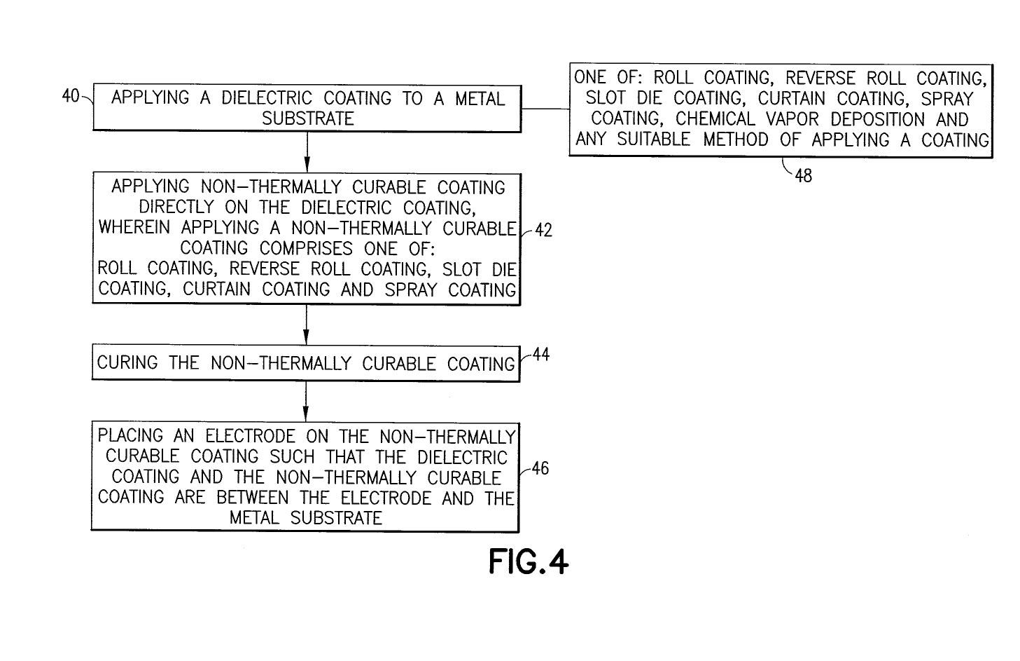

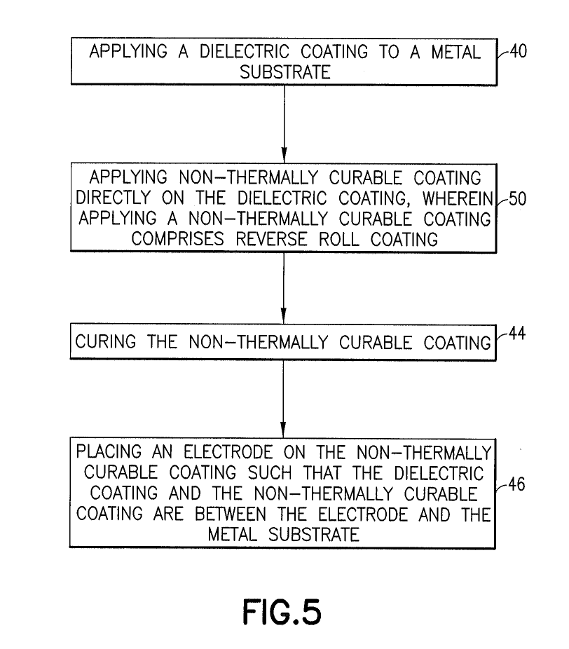

FIG. 4 illustrates another embodiment of a method of making an opto-electric device, wherein applying a dielectric coating comprises one of: roll coating, reverse roll coating, slot die coating, curtain coating, spray coating, chemical vapor deposition and chemical vapor deposition 48. Reverse roll coating allows good control of the thickness of the coating and a relatively thick coating can be applied in a single layer or single application. In some embodiments, a 5-30 micron coating can be applied in a single layer or single application via reverse roll coating. Also, reverse roll coating can be used to apply the dielectric or the non-thermally curable coating quickly. In some embodiments, web speeds range from 100-550 foot/minute.

FIG. 5 illustrates another embodiment of a method of making an opto-electric device wherein applying a non-thermally curable coating comprises reverse roll coating 50.

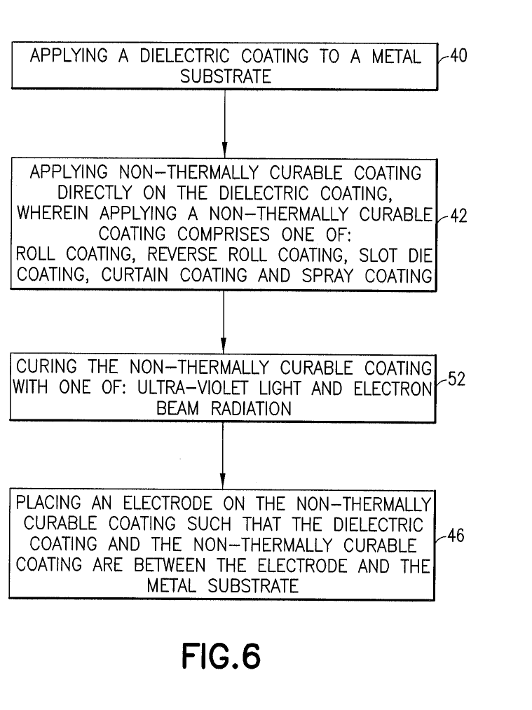

FIG. 6 illustrates another embodiment of a method of making an opto-electric device wherein, the non-thermally curable coating is cured by one of: ultra-violet light and electron beam radiation 52.

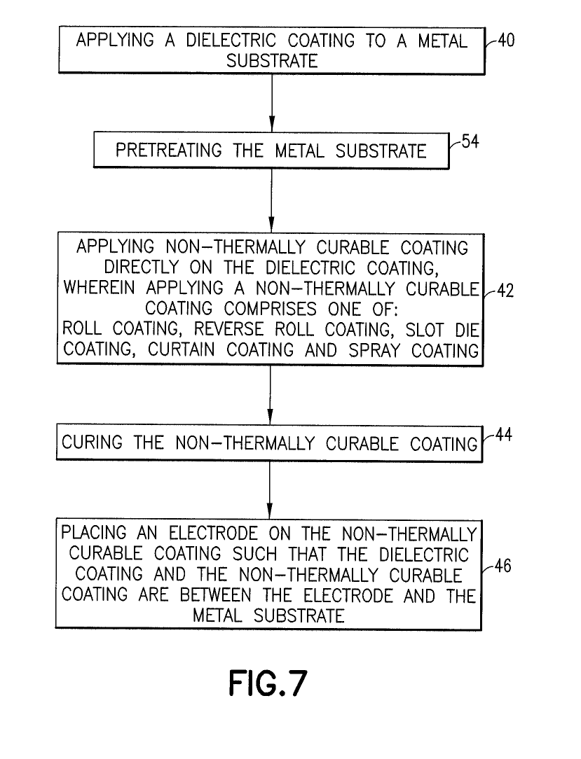

FIG. 7 illustrates another embodiment of a method of making an opto-electric device further comprising pretreating the substrate 54 before applying the dielectric coating 40.

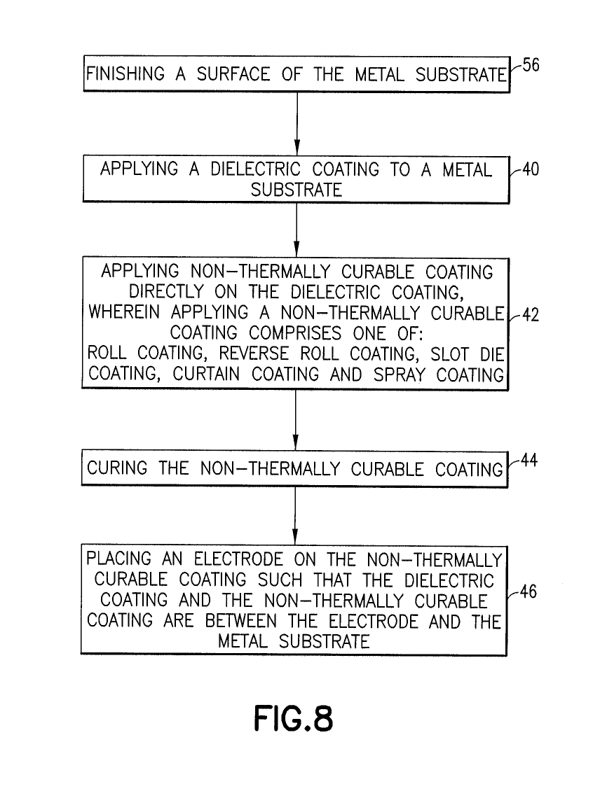

FIG. 8 illustrates another embodiment of a method of making an opto-electric device further comprising finishing a surface of the substrate 56. In some embodiments, the surface of the substrate is finished so that the surface of the substrate has an average surface roughness Rz of 150 nm to 350 nm. In some embodiments, the surface of the substrate is finished so that the surface of the substrate has an average surface roughness Rz of 175 nm to 350 nm. In other embodiments, the surface of the substrate is finished so that the surface of the substrate has an average surface roughness Rz of 200 nm to 350 nm. In another embodiment, the surface of the substrate is finished so that the surface of the substrate has an average surface roughness Rz of 200 nm to 300 nm.

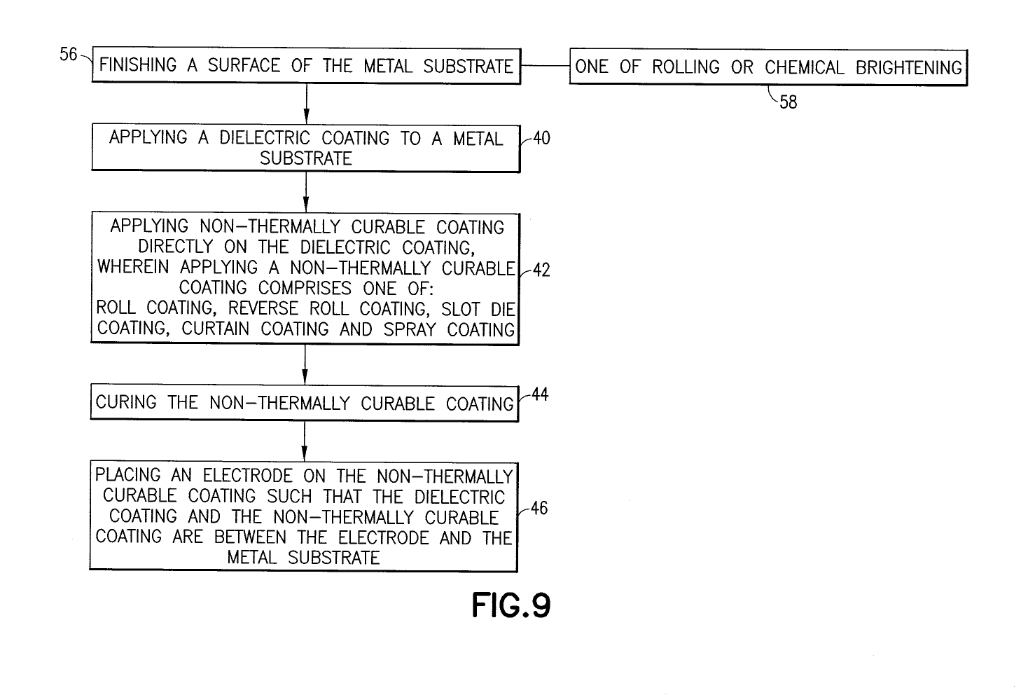

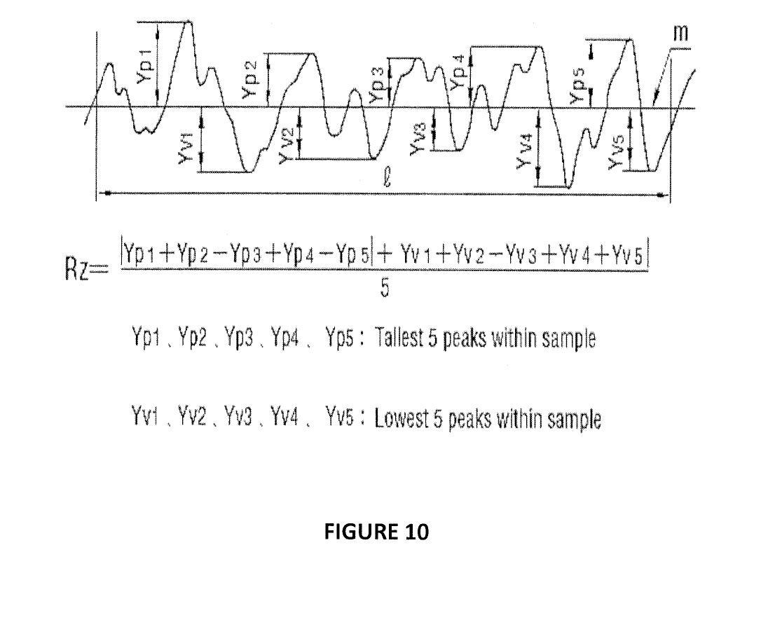

FIG. 9 illustrates another embodiment of a method of making an opto-electric device wherein finishing comprises one of rolling or chemical brightening 58.

Some embodiments of the method include cleaning the surface of the substrate before applying the dielectric layer. Any cleaning techniques known in the art may be used, including, but not limited to use of sodium carbonate, aqueous alkaline, surfactants and other non-etching cleaners.

Some embodiments of the method include applying a pretreatment coating.

In some embodiments, the dielectric layer also serves as a planarization layer and reduces the surface roughness of the substrate. In some embodiments, the non-thermally curable coating functions as a buffer between the substrate coated with a dielectric planarizing layer and subsequent layers in an opto-electric stack. The non-thermally curable coating encapsulates debris and defects on the dielectric layer resulting in a surface with very low density surface imperfections. Coating systems that do not involve the use of solvents reduce the amount of volatile materials and debris that are generated during curing.

In one embodiment, spray coating is used to apply 100% weight solid epoxy acrylates directly on the dielectric coating layer. Then the epoxy acrylates are cured with ultra-violet radiation. Using spray coating or reverse roll coating to apply 100% weight solid epoxy acrylates directly on the dielectric coating layer does not require use of a vacuum chamber and utilizes only one process step. It can be done in a continuous process and is suitable for a high volume manufacturing. Reverse roll coating, slot die coating and curtain coating are alternate processing options which could also be used for continuous processing instead of spray coating.

Some embodiments of the invention have one or more of the following characteristics:

| | | |
|---|---|---|
| Surface roughness, Ra/Rz (AFM) (as | 1.5 nm/21 nm | For aluminum, two substrates |
| measured by Atomic Force Microscopy) | | having similar AFM surface |
| | | values can perform differently. |
| | | (Pixel yield would be the most |
| | | important difference. This |
| | | results in non-uniform light |
| | | emission.) (Sometimes, a |
| | | substrate may short and a |
| | | substrate having a similar AFM |
| | | value may not short. Shorting |
| | | means current flows through |
| | | an unintended path). The area |
| | | examined by AFM is small. |
| | | Adjoining areas —not |
| | | examined—can be rougher which |
| | | explains performance |
| | | differences. |
| Surface Roughness, Rzmax as measured by | <100 nm | Use of Rz, rather than Ra, |
| Phase Shift. Phase Shift is an optical | | provides more representative |
| profilometer that detects surface | | topography of the surface. |
| roughness based upon the phase change | | Surface peaks and valleys can |
| (i.e., shift) in the light impinging upon a | | be detected over a larger area |
| surface. | | compared to AFM data. |
| Surface roughness after electrode | No change | |
| deposition | | |
| Resistivity, ohm-cm | 9.79E−06 | |
| Electrode Compatibility | | |
| Adhesion (Tape test) | Pass | As measured by ASTM D3359- |
| | | 02 using high tack tape pull |
| | | test. |
| Wetting (Surface evaluation) | Excellent | “Excellent” refers to the |
| | | compatibility between the |
| | | material being deposited and |
| | | the surface being coated. |
| | | Wetting can be measured |
| | | visually or by contact angle |
| | | measurements. Since the |
| | | electrodes are vapor deposited, |
| | | excellent compatibility means |
| | | that the metallic atoms (for |
| | | example, silver for the bottom |
| | | electrode) form a |
| | | smooth/uniform layer on the |
| | | coated substrate without any |
| | | voids/holes in the electrode |
| | | layer. |
| OLED Performance | | |
| Pixel Yields (16 small 2.0 mm Pixels test ) | 16/16 | |
| Pixels Uniformity (1.0 sq. inch. Pixels Test) | No dark spots or shorts | |
| JV characteristics (Current/voltage | Same as or better than | Current/voltage (J/V) scans of |
| (J/V)scans) | baseline as measured using | OLED structures made on glass |
| | the same test methods and | provide control measurements. |
| | conditions (Baseline is a | This is the baseline for |
| | glass substrate having the | comparison against other |
| | same OLED stack structure | materials. |
| | and layer thickness.) | |
| Encapsulation, 1000 hrs Ca test in an | Same as or better than | |
| accelerated environment The Calcium test | baseline | |
| involves depositing a layer of elemental | | |
| calcium—which has an opaque brown color— | | |
| onto the surface inside an encapsulated | | |
| device. Elemental calcium will form a | | |
| transparent oxide (CaO) when exposed to | | |
| water vapor. When the appearance | | |
| changes from an opaque brown to a | | |
| transparent clear, it indicates that the | | |
| encapsulation is not hermetic. Accelerated | | |
| testing conditions utilize higher | | |
| temperature and humidity, (e.g., 85 | | |
| degrees C. & 85% relative humidity (RH)). | | |

Although the present invention has been described in considerable detail with reference to certain versions thereof, other versions are possible. Therefore, the spirit and scope of the appended claims should not be limited to the description of the versions contained herein.

All features disclosed in the specification, including the claims, abstracts, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means” for performing a specified function or “step” for performing a specified function should not be interpreted as a “means or step for” clause as specified in 35 U.S.C. §112.

1. An opto-electric device comprising:
a. a substrate; wherein the substrate in an uncoated condition has an average surface roughness Rz of 150 nm to 1500 nm;
b. a dielectric coating on the substrate;
c. a non-thermally curable coating directly on the dielectric coating; and
d. an electrode on the non-thermally curable coating; wherein the dielectric coating and the non-thermally curable coating are between the electrode and the substrate; wherein the substrate is one of: metal or plastic.

2. The device of claim 1 wherein the substrate in an uncoated condition has an average surface roughness Rz of 150 nm to 350 nm.

3. The device of claim 1 wherein the substrate in an uncoated condition has an average surface roughness Rz of 175 nm to 350 nm.

4. The device of claim 1 wherein the substrate in an uncoated condition has an average surface roughness Rz of 200 nm to 350 nm.

5. The device of claim 1 wherein the substrate in an uncoated condition has an average surface roughness Rz of 200 nm to 300 nm.

6. The device of claim 1 wherein the substrate with the dielectric coating has an average surface roughness Rz of 35 nm to 250 nm.

7. The device of claim 1 wherein the substrate with the dielectric coating has an average surface roughness Rz of 75 nm to 150 nm.

8. The device of claim 1 wherein the substrate with the dielectric coating has an average surface roughness Rz of 90 nm to 110 nm.

9. The device of claim 1 wherein the thickness of the non-thermally curable coating is in the range of 1 to 30 microns.

10. The device of claim 1 wherein the thickness of the non-thermally curable coating is in the range of 3 to 18 microns.

11. The device of claim 1 wherein the thickness of the non-thermally curable coating is in the range of 8 to 12 microns.

12. A method of making an opto-electric device comprising:
a. applying a dielectric coating to a substrate, wherein the substrate is one of: metal or plastic;
b. applying a non-thermally curable coating directly on the dielectric coating; wherein applying a non-thermally curable coating comprises one of: roll coating, reverse roll coating, slot die coating, curtain coating and spray coating;
c. curing the non-thermally curable coating; and
d. placing an electrode on the non-thermally curable coating such that the dielectric coating and the non-thermally curable coating are between the electrode and the substrate.

13. The method of claim 12 wherein applying a non-thermally curable coating comprises applying the non-thermally curable coating via a continuous process.

14. The method of claim 12 further comprising finishing a surface of the substrate so that the surface of the substrate has an average surface roughness Rz of 150 nm to 1500 nm.

15. The method of claim 12 further comprising finishing a surface of the substrate so that the surface of the substrate has an average surface roughness Rz of 150 nm to 350 nm.

16. The method of claim 12 further comprising finishing a surface of the substrate so that the surface of the substrate has an average surface roughness Rz of 200 nm to 350 nm.

17. The method of claim 12 further comprising finishing a surface of the substrate so that the surface of the substrate has an average surface roughness Rz of 200 nm to 300 nm.

18. The method of claim 12 wherein finishing comprises one of: rolling and chemical brightening.

19. The method of claim 12 wherein applying a non-thermally curable coating comprises one of: spray coating, roll coating and reverse roll coating.

20. The method of claim 19 wherein applying a non-thermally curable coating comprises reverse roll coating.
